(19) United States
(12) Patent Application Publication
(10) Pub. No.: US 2018/0057938 A1
(43) Pub. Date: Mar. 1, 2018

(54) VAPOR-PHASE GROWTH METHOD

(71) Applicant: NuFlare Technology, Inc., Kanagawa (JP)

(72) Inventors: Hideshi TAKAHASHI, Yokohama (JP); Yasushi IYECHIKA, Matsudo (JP); Masayuki TSUKUI, Yokohama (JP)

(21) Appl. No.: 15/687,839

(22) Filed: Aug. 28, 2017

(30) Foreign Application Priority Data
Aug. 29, 2016 (JP) 2016-167132

(51) Int. Cl. C23C 16/452; H01L 21/027

(52) U.S. Cl. CPC C23C 16/452; H01L 21/0271

(57) ABSTRACT

A substrate W is placed on a support part 7 provided in a reaction chamber 2. While the substrate W is rotated together with the support part 7 around a rotation shaft A passing through a center of the substrate W at a rotating speed of 1300 rpm or more and 2000 rpm or less, a source gas including an organic metal is supplied onto the substrate W from a portion above the reaction chamber 2 to cause a III-V semiconductor layer to grow on the substrate W.

### CROSS-REFERENCE TO RELATED APPLICATIONS

This application is based upon and claims the benefit of priority from Japanese Patent Application No. 2016-167132, filed on Aug. 29, 2016, the entire contents of which are incorporated herein by reference.

### FIELD

The embodiments of the present invention relate to a vapor-phase growth method.

### BACKGROUND

In recent years, a GaN HEMT (High Electron Mobility Transistor) that is expected to have a high breakdown voltage and a very low ON resistance has been developed for use as a power semiconductor device, for example. In this GaN device, an AlGaN/GaN heterostructure is used, for example, and a MOCVD (Metal Organic Chemical Vapor Deposition) method is used for forming layers of the heterostructure.

When an AlGaN layer is formed, trimethylaluminum (TMA) gas, trimethylgallium (TMG) gas, and a gas including ammonium are supplied as source gases into a chamber in which a wafer of Si or the like is placed. The supplied source gases are caused to react with one another on the heated wafer to cause the AlGaN layer to grow on the wafer.

### SUMMARY

However, in a conventional MOCVD method, trimethylaluminum and ammonium react with each other in a vapor phase before reaching the wafer. Therefore, there has been a problem that it is difficult to ensure uniformity (hereinafter, also “in-plane uniformity”) of the thickness of the AlGaN layer and an Al concentration in the AlGaN layer in a wafer plane.

It is an object of the present invention to provide a vapor-phase growth method that can improve in-plane uniformity of a III-V semiconductor layer.

In a vapor-phase growth method according to an aspect of the present invention, a substrate is placed on a support part provided in a reaction chamber and a source gas including an organic metal is supplied onto the substrate from a portion above the reaction chamber, while the substrate is rotated together with the support part around a rotation axis passing through a center of the substrate at a rotating speed of 1300 rpm or more and 2000 rpm or less, to cause a III-V semiconductor layer to grow on the substrate.

### BRIEF DESCRIPTION OF THE DRAWINGS

FIG. 1 is a plan view illustrating an example of a vapor-phase growth device that can be applied to a vapor-phase growth method according to the present embodiment;

FIG. 2 is a cross-sectional view of the vapor-phase growth device of FIG. 1;

FIG. 3 is a graph illustrating a first experimental example of the vapor-phase growth method;

FIG. 4 is a graph illustrating a second experimental example of the vapor-phase growth method; and

FIG. 5 is a graph illustrating a third experimental example of the vapor-phase growth method.

### DETAILED DESCRIPTION

An embodiment of the present invention will now be explained below with reference to the accompanying drawings. The present invention is not limited to the embodiment.

### (Vapor-Phase Growth Device 1)

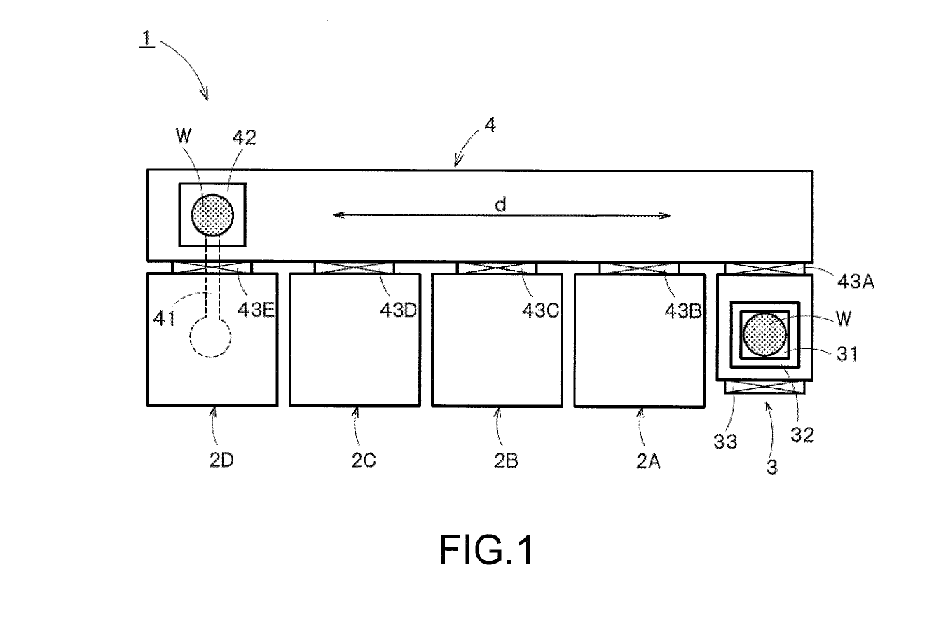

FIG. 1 is a plan view illustrating an example of a vapor-phase growth device 1 that can be applied to a vapor-phase growth method according to the present embodiment. The vapor-phase growth device 1 of FIG. 1 is a single-wafer type epitaxial growth device that uses a MOCVD method. As illustrated in FIG. 1, the vapor-phase growth device 1 includes four chambers 2A to 2D that are an example of a reaction chamber, a cassette chamber 3, and a transfer chamber 4.

Each of the chambers 2A to 2D processes a wafer W that is an example of a substrate under a pressure less than atmospheric pressure. The chambers 2A to 2D are arranged straight along a transfer direction d in the transfer chamber 4. The vapor-phase growth device 1 can efficiently process a plurality of wafers W because it includes the plural chambers 2A to 2D.

The cassette chamber 3 includes a placing table 32 that allows a cassette 31 holding the plural wafers W to be placed thereon. The cassette 31 is made of a resin or aluminum, for example. The cassette chamber 3 is provided with a gate valve 33. The cassette 31 can be transferred into the cassette chamber 3 from outside through the gate valve 33. A pressure in the cassette chamber 3 can be reduced to a pressure less than atmospheric pressure by a vacuum pump (not illustrated), while the gate valve 33 is closed.

The transfer chamber 4 is provided between the cassette chamber 3 and the chambers 2A to 2D. In the transfer chamber 4, the wafer W is transferred in the transfer direction d between the cassette chamber 3 and the chambers 2A to 2D under a pressure less than atmospheric pressure. More specifically, the wafer W before epitaxial growth is transferred from the cassette chamber 3 to the chambers 2A to 2D, and the wafer W after epitaxial growth is transferred from the chambers 2A to 2D to the cassette chamber 3. A robot arm 41 and a placing table 42 are provided in the transfer chamber 4. The robot arm 41 can deliver and receive the wafer W to/from the cassette chamber 3 or the chambers 2A to 2D. The placing table 42 can move in the transfer direction d with the wafer W and the robot arm 41 placed thereon. Therefore, it is possible to move the robot arm 41 that has received the wafer W before epitaxial growth from the cassette chamber 3 to each of the chambers 2A to 2D by the placing table 42, and to transfer the wafer W held by the robot arm 41 into the chambers 2A to 2D. Further, it is possible to move the robot arm 41 that has received the wafer W after epitaxial growth from each of the chambers 2A to 2D to the cassette chamber 3 by the placing table 42, to collect the wafer W held by the robot arm 41 into the cassette chamber 3.

Gate valves 43A to 43E that can be opened and closed are provided between the cassette chamber 3 and the transfer chamber 4 and between the transfer chamber 4 and the chambers 2A to 2D. By opening the gate valve 43A, the wafer W can be moved between the cassette chamber 3 and the transfer chamber 4. Also, by opening each of the gate valves 43B to 43E, the wafer W can be moved between the transfer chamber 4 and a corresponding one of the chambers 2A to 2D.

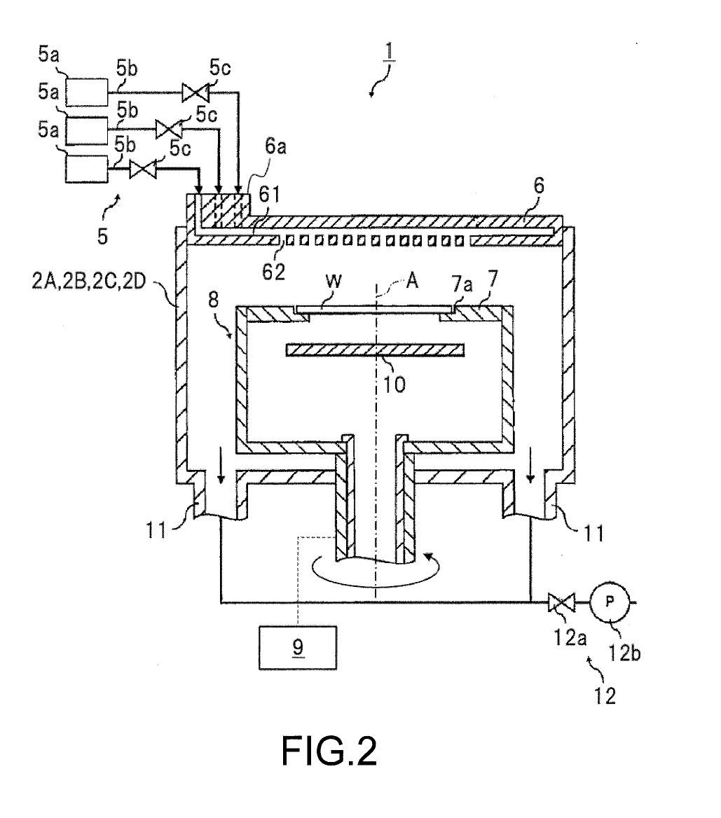

FIG. 2 is a cross-sectional view of the vapor-phase growth device 1 of FIG. 1. FIG. 2 illustrates an internal configuration of each of the chambers 2A to 2D of the vapor-phase growth device 1 of FIG. 1, together with an upstream gas channel and a downstream gas channel of the chambers 2A to 2D.

As illustrated in FIG. 2, the vapor-phase growth device 1 includes the above configuration and further includes a gas supply part 5, a shower head 6, a susceptor 7 that is an example of a support part, a rotary part 8, a rotating mechanism 9, a heater 10, a gas discharger 11, and an exhaust mechanism 12.

The gas supply part 5 is connected to the chambers 2A to 2D on a gas upstream side. The gas supply part 5 includes a plurality of reservoirs 5a, a plurality of gas pipes 5b, and a plurality of gas valves 5c. Each of the reservoirs 5a stores a gas or a gas liquid precursor therein. When a III-V semiconductor layer is caused to grow on the wafer W, a source gas of the III-V semiconductor layer or its liquid precursor is stored in each reservoir 5a. For example, when an AlGaN layer is caused to grow as the III-V semiconductor layer, trimethylaluminum liquid, trimethylgallium liquid, and ammonium are stored in the respective reservoirs 5a.

Trimethylaluminum stored in the reservoir 5a becomes a first source gas including trimethylaluminum (hereinafter, also “TMA gas”) as an example of a group III source gas by being subjected to bubbling, that is, being vaporized with a carrier gas, such as hydrogen gas. Trimethylgallium stored in the reservoir 5a becomes a second source gas including trimethylgallium (hereinafter, also “TMG gas”) as an example of the group III source gas by being subjected to bubbling with a carrier gas, such as hydrogen gas. When an AlGaN layer is caused to grow, ammonium gas that is an example of a third source gas, that is, a group V source gas is supplied to the chambers 2A to 2D while TMA gas and TMG gas are supplied.

The gas pipes 5b connect each of the reservoirs 5a and a gas introduction part 6a to each other. The gas valves 5c are provided in the gas pipes 5b, respectively. Each gas valve 5c can adjust the flow rate of a gas flowing in a corresponding gas pipe 5b. A plurality of pipe configurations can be actually employed, for example, in which a plurality of gas pipes are joined, a single gas pipe branches to a plurality of gas pipes, and branching and joining of the gas pipes are combined.

The gas introduction part 6a is connected to the shower head 6 provided in an upper portion of the chambers 2A to 2D. The shower head 6 has a shower plate 61 on its bottom side. The shower plate 61 is provided with a plurality of gas outlets 62. The shower plate 61 can be configured by using a metal source, for example, stainless steel or aluminum alloy. A plurality of gases respectively supplied from the gas pipes 5b are introduced into the shower head 6. The introduced gases are mixed in the shower head 6, and are then supplied into the chambers 2A to 2D through the gas outlets 62 of the shower plate 61. A plurality of gas channels extending laterally may be provided in the shower plate 61, so that a plurality of types of gases are supplied to the wafer W in the chambers 2A to 2D while being separated from each other.

The susceptor 7 supports the wafer W in the chambers 2A to 2D in such a manner that the wafer W is placed horizontally. The susceptor 7 is provided in an upper portion of the rotary part 8, and supports the wafer W placed in a recess 7a provided on an inner circumferential side of the susceptor 7. Although the susceptor 7 has an annular shape having an opening at its center in the example of FIG. 2, the susceptor 7 may be an approximately flat plate with no opening. Further, although the susceptor 7 supports a single wafer W in the example of FIG. 2, the susceptor 7 may support a plurality of wafers W, for example, four wafers W.

The rotary part 8 rotates in the chambers 2A to 2D around a rotation axis A that extends vertically, while holding the susceptor 7. The rotation axis A passes through the center of the susceptor 7 and a center of the wafer W. By rotation of the rotary part 8, the susceptor 7 held by the rotary part 8 rotates around the rotation axis A together with the wafer W supported by the susceptor 7.

The rotating mechanism 9 drives and rotates the rotary part 8. For example, the rotating mechanism 9 includes a driving source, such as a motor, a controller that controls the driving source, and a transmission member that transmits a driving force of the driving source to the rotary part 8, such as a timing belt or a gear. The rotating mechanism 9 rotates the wafer W at a predetermined rotating speed.

During formation of a III-V semiconductor layer described later, the rotating speed of the wafer W is controlled to be 1300 rpm or more and 2000 rpm or less in order to improve in-planar uniformity.

The heater 10 heats the susceptor 7 and the wafer W from below. A specific heating method of the heater 10 is not particularly limited. For example, resistance heating, lamp heating, or induction heating may be employed.

The gas discharger 11 discharges the source gases after reaction from the inside of the chambers 2A to 2D to outside.

The exhaust mechanism 12 controls the inside of the chambers 2A to 2D to have a desired pressure by operations of an exhaust valve 12a and a vacuum pump 12b through the gas discharger 11.

### (Vapor-Phase Growth Method)

A vapor-phase growth method, that is, a deposition method that uses the single-wafer type vapor-phase growth device 1 configured in the above manner is described. In the vapor-phase growth method described below, an AlGaN layer is caused to grow as a III-V semiconductor layer by a MOCVD method. Further, the description of a process of a semiconductor layer in a HEMT other than the AlGaN layer, such as an AlN layer, is omitted in the following description.

The robot arm 41 and the placing table 42 in the transfer chamber 4 transfer the wafer W from the cassette chamber 3 to the chambers 2A to 2D through the gate valve 43A and a corresponding one of the gate valves to 43B to 43E. The robot arm 41 then places the transferred wafer W on the susceptor 7.

An inert gas, such as H₂, N₂, or Ar, is supplied into the chambers 2A to 2D at a predetermined flow rate from the gas introduction part 6a through the shower head 6 and the gas outlets 62. After the wafer W is placed on the susceptor 7, the gate valves 43A to 43E are closed. The exhaust mechanism 12 then exhausts air in the inside of the chambers 2A to 2D through the gas discharger 11 to adjust a pressure in the chambers 2A to 2D to a desired pressure.

The wafer W is heated by the heater 10 to an epitaxial growth temperature, for example, 1000° C. or higher and 1100° C. or lower.

The rotating mechanism 9 rotates the wafer W around the rotation axis A at a predetermined rotating speed via the rotary part 8 and the susceptor 7.

While the wafer W is rotated, the gas supply part 5 supplies TMA gas and TMG gas into the chambers 2A to 2D, together with ammonium gas.

TMA gas, TMG gas, and ammonium gas supplied from the gas supply part 5 are introduced into the shower head 6 provided in an upper portion of the chambers 2A to 2D, and are mixed in the shower head 6. The mixture of TMA gas, TMG gas, and ammonium gas is discharged toward the wafer W from the gas outlets 62 of the shower plate 61.

In this manner, while source gases are supplied onto the wafer W at a predetermined flow rate, the wafer W is heated to a predetermined temperature and is rotated at the predetermined rotating speed. With this operation, an AlGaN layer is formed on the wafer W.

Here, a region in a thickness direction on a surface of the wafer W, in which vapor phase reaction occurs, is referred to as a boundary layer. When the rotating speed of the wafer W is low, it is considered that a thick, non-uniform boundary layer is formed on the wafer W. When the boundary layer is thick, vapor phase reaction of the source gases in the boundary layer occurs before the source gases reach the wafer W. Therefore, a speed of growth is lowered. Further, in order to form an AlGaN layer, TMA gas for which vapor phase reaction can occur relatively easily and TMG gas for which vapor phase reaction hardly occurs are made to flow simultaneously to cause reaction with ammonium gas and deposition of the AlGaN layer. Therefore, TMA and ammonium preferentially react with each other because of a behavior of gases in the boundary layer, so that TMA and ammonium form particles and are exhausted without contributing to growth of the AlGaN layer. In this manner, a distribution is generated in vapor phase reaction, which causes not only the layer thickness but also an in-plane distribution of Al to be lowered. Particularly, vapor phase reaction can proceed more easily in a case where the gases are mixed in the shower head 6 and are then supplied to the chambers 2A to 2D.

On the other hand, in the present embodiment, the wafer W is rotated at a high rotating speed of 1300 rpm or more. Due to a combination of this high-speed rotation and a flow of the source gases falling down from the shower plate 61 toward the wafer W, it is possible to form a thin and uniform boundary layer on the wafer W.

When the rotating speed of the wafer W is lower than 1300 rpm, it is difficult to ensure in-plane uniformity of the AlGaN layer. Meanwhile, when the rotating speed is higher than 2000 rpm, vibration, slippage, jump, or the like caused by small misalignment of the wafer W or the rotating mechanism 9, or the like occurs, and makes stable deposition difficult.

Therefore, by setting the rotating speed of the wafer W to 1300 rpm or more and 2000 rpm or less, it is possible to improve the in-plane uniformity of the AlGaN layer stably. Further, by setting the rotating speed to 1300 rpm or more and 2000 rpm or less, uniformity of an Al composition in a wafer plane can be also improved, in addition to the in-plane uniformity of the thickness of the AlGaN layer, as described later. The rotating speed of the wafer W is preferably 1500 rpm or more, and is more preferably 1500 rpm or more and 1700 rpm or less.

By forming the thin and uniform boundary layer, it is possible to suppress occurrence of vapor phase reaction of the source gases before the source gases reach the wafer W. Also, the thin boundary layer allows the source gases to be easily taken into the surface of the wafer W, so that the thin boundary layer can accelerate uniform vapor phase reaction on the surface of the wafer W. Further, the particles on the wafer W can be efficiently discharged from an area on the wafer W by a centrifugal force generated by high-speed rotation of the wafer W. That is, the source gases supplied onto the wafer W from a portion above the chambers 2A to 2D form the boundary layer on the wafer W, and are discharged from an outer periphery of the wafer W. With this operation, the AlGaN layer can be caused to grow with high in-plane uniformity on the surface of the wafer W.

Further, because the single-wafer type vapor-phase growth device 1 is used in the vapor-phase growth method of the present embodiment, a more stable gas flow can be obtained as compared with a case of using a batch type vapor-phase growth device, and it is possible to cause the AlGaN layer to epitaxially grow stably.

An underlying structure of the AlGaN layer is not particularly limited, as long as it allows the AlGaN layer to epitaxially grow. For example, the underlying structure may be an AlN buffer layer formed on an AlN substrate that is an example of the wafer W.

The vapor-phase growth method of the present embodiment can be also effectively applied to growth of a III-V semiconductor layer other than the AlGaN layer, for example, an AlN layer, a GaN layer, an InGaN layer, and a pGaN layer.

### Experimental Examples

Experimental examples of a vapor-phase growth method are described.

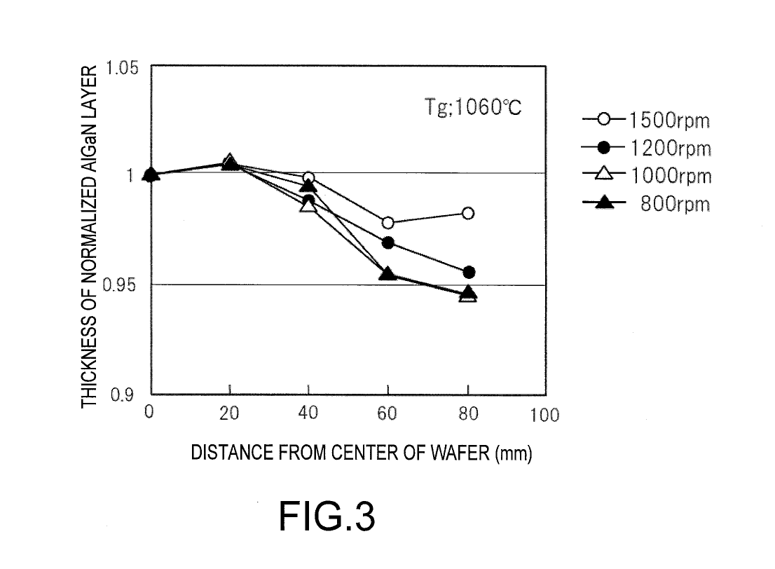

FIG. 3 is a graph illustrating a first experimental example of the vapor-phase growth method. In the first experimental example, four rotating speeds of 800 rpm, 1000 rpm, 1200 rpm, and 1500 rpm were used as a rotating speed of the wafer W. At each rotating speed, an AlGaN layer was caused to epitaxially grow on the wafer W by a MOCVD method. The heating temperature of the wafer W by the heater 10 was set to 1060° C. The thickness of the AlGaN layer growing at each rotating speed was measured at each of a center of the wafer W, a position 20 mm away from the center, a position 40 mm away from the center, a position 60 mm away from the center, and a position 80 mm away from the center. An X-ray diffractometer was used in measurement of the thickness and a composition of the AlGaN layer. The measurement results of the thickness of the AlGaN layer are represented as a graph as illustrated in FIG. 3. In FIG. 3, the horizontal axis represents a distance from the center of the wafer W, and the vertical axis represents the thickness of the AlGaN layer at each measurement position that is normalized by regarding the thickness of the AlGaN layer at the center of the wafer W as 1.

As illustrated in FIG. 3, when the rotating speed of the wafer W was 800 rpm, 1000 rpm, and 1200 rpm, a ratio of a maximum value max of the thickness of the AlGaN layer and a minimum value mix thereof (hereinafter, also “min/max”) was less than 0.96. For example, in order to obtain favorable HEMT characteristics, it is preferable that in-plane uniformity of the AlGaN layer, that is, min/max is 0.96 or more. However, when the rotating speed was 800 rpm, 1000 rpm, and 1200 rpm, this condition was not satisfied. On the other hand, when the rotating speed of the wafer W was 1500 rpm, it was possible to obtain min/max larger than 0.96. It can be estimated that the above condition can be satisfied when the rotating speed is about 1300 rpm.

Therefore, according to the first experimental example, it was confirmed that in-plane uniformity of the AlGaN layer was able to be improved to a satisfactory level by setting the rotating speed of the wafer W to 1300 rpm or more. Also, according to the first experimental example, it was confirmed that in-plane uniformity of the AlGaN layer was able to be improved more effectively by setting the rotating speed of the wafer W to 1500 rpm or more.

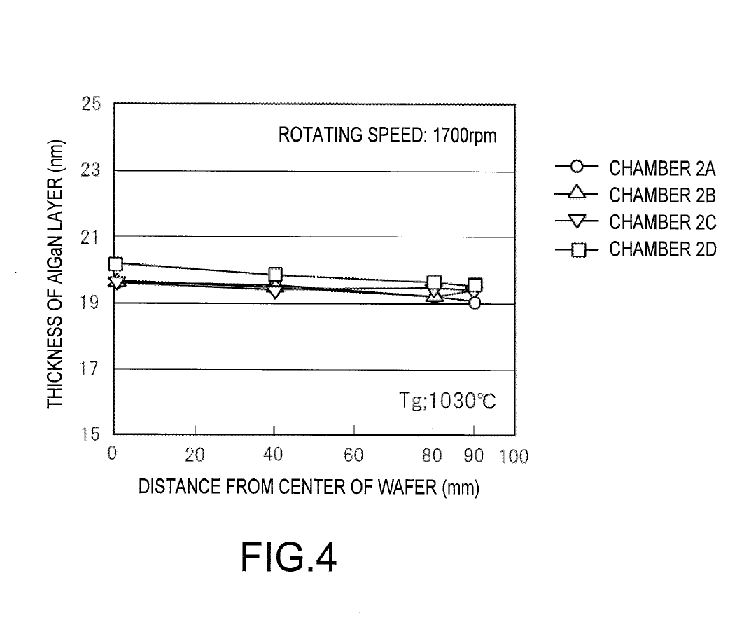

FIG. 4 is a graph illustrating a second experimental example of the vapor-phase growth method. In the second experimental example, an AlGaN layer was caused to epitaxially grow on the wafer W by a MOCVD method in each of the four chambers 2A to 2D of the vapor-phase growth device 1 of FIG. 1, while the wafer W was rotated at 1700 rpm. A heating temperature Tg of the wafer W by the heater 10 was set to 1030° C. The thickness of the AlGaN layer growing in each of the chambers 2A to 2D was measured at each of a center of the wafer W, a position 20 mm away from the center, a position 40 mm away from the center, a position 60 mm away from the center, a position 80 mm away from the center, and a position 90 mm away from the center. The measurement results of the thickness of the AlGaN layer are represented as a graph as illustrated in FIG. 4. In FIG. 4, the horizontal axis represents a distance from the center of the wafer W, and the vertical axis represents the thickness of the AlGaN layer.

As illustrated in FIG. 4, it was found that in all the four chambers 2A to 2D, the difference between the maximum thickness and the minimum thickness of the AlGaN layer was able to be suppressed within 1 nm. This is sufficiently favorable as in-plane uniformity. Further, the results in FIG. 4 show that in-plane uniformity in each of the chambers 2A to 2D is favorable, and also show that interplanar uniformity that is uniformity of the thickness of the AlGaN layer among the chambers 2A to 2D is also favorable.

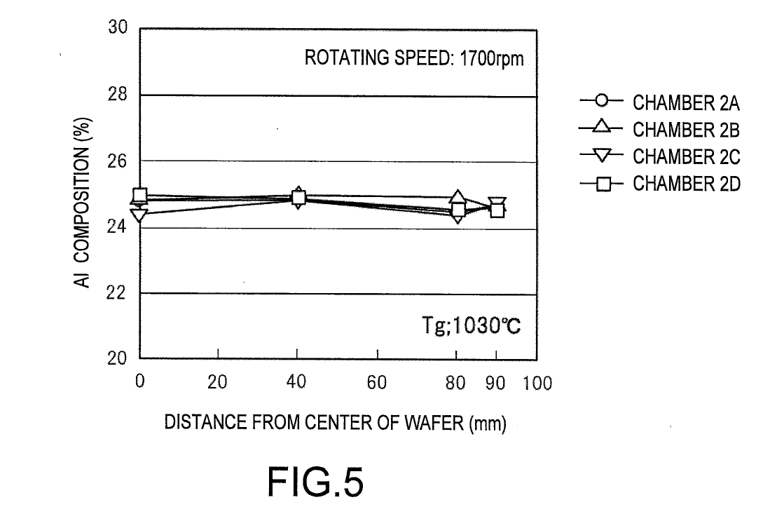

FIG. 5 is a graph illustrating a third experimental example of the vapor-phase growth method. Growth conditions of an AlGaN layer in the third experimental example are the same as those in the second experimental example. In the third experimental example, an Al composition (%) in the AlGaN layer that epitaxially grew in each of the chambers 2A to 2D was measured at each of a center of the wafer W, a position 20 mm away from the center, a position 40 mm away from the center, a position 60 mm away from the center, a position 80 mm away from the center, and a position 90 mm away from the center.

The measurement results of the Al composition in the AlGaN layer are represented as a graph as illustrated in FIG. 5. In FIG. 5, the horizontal axis represents a distance from the center of the wafer W, and the vertical axis represents the Al composition in the AlGaN layer.

As illustrated in FIG. 5, it was found that the Al composition in the AlGaN layer was able to be uniformly controlled to be about 25% at each measurement position in all the four chambers 2A to 2D. The Al composition of about 25% indicates that favorable Al composition is obtained as a composition of the AlGaN layer.

As described above, according to the present embodiment, it is possible to improve in-plane uniformity of a III-V semiconductor layer by using a MOCVD method in which a rotating speed of the wafer W is set to 1300 rpm or more and 2000 rpm or less.

The embodiment described above has been presented by way of example only and is not intended to limit the scope of the invention. The embodiment can be implemented in a variety of other forms, and various omissions, substitutions and changes can be made without departing from the spirit of the invention. The embodiment and modifications thereof are included in the scope of invention described in the claims and their equivalents as well as the scope and the spirit of the invention.

1. A vapor-phase growth method comprising:
placing a substrate on a support part provided in a reaction chamber; and
supplying a source gas including an organic metal onto the substrate from a portion above the reaction chamber, while the substrate is rotated together with the support part around a rotation axis passing through a center of the substrate at a rotating speed of 1300 rpm or more and 2000 rpm or less, to cause a III-V semiconductor layer to grow on the substrate.

2. The method of claim 1, wherein the source gas includes a group III source gas and a group V source gas.

3. The method of claim 2, wherein the group III source gas includes aluminum.

4. The method of claim 2, wherein the group III source gas and the group V source gas are mixed and then supplied into the reaction chamber.

5. The method of claim 1, wherein the source gas includes a first source gas including trimethylaluminum, a second source gas including trimethylgallium, and a third source gas including ammonium gas.

6. The method of claim 1, wherein the III-V semiconductor layer is an AlGaN layer.

7. The method of claim 1, wherein a rotating speed of the substrate is 1500 rpm or more and 1700 rpm or less.

8. The method of claim 1, wherein the substrate is an Si substrate.

9. The method of claim 1, wherein the substrate is heated, while the substrate is rotated and the source gas is supplied onto the substrate.

10. The method of claim 1, wherein the source gas supplied onto the substrate from a portion above the reaction chamber forms a boundary layer on the substrate and is discharged from an outer periphery of the substrate.
